(19) United States
(12) Patent Application Publication
(10) Pub. No.: US 2025/0120284 A1
(43) Pub. Date: Apr. 10, 2025

(54) DISPLAY DEVICE AND MANUFACTURING METHOD OF DISPLAY DEVICE

(71) Applicant: Samsung Display Co., LTD., Yongin-si (KR)

(72) Inventor: Hyun Eok SHIN, Yongin-si (KR)

(21) Appl. No.: 18/616,958

(22) Filed: Mar. 26, 2024

(30) Foreign Application Priority Data
Oct. 6, 2023 (KR) 10-2023-0133651

(51) Int. Cl. H10K 59/80; H10K 59/131

(52) U.S. Cl. CPC H10K 59/80522; H10K 59/131; H10K 59/80523

(57) ABSTRACT

A display device includes: a substrate; a light emitting diode including a common electrode on the substrate; a first conductive layer on the common electrode and contacting the common electrode; a first insulating layer over the first conductive layer and having a first contact opening over the first conductive layer; and a common voltage line on the first insulating layer and electrically connected to the first conductive layer through the first contact opening.

### CROSS-REFERENCE TO RELATED APPLICATION

The present application claims priority to and the benefit of Korean Patent Application No. 10-2023-0133651, filed on Oct. 6, 2023, in the Korean Intellectual Property Office, the entire disclosure of which is incorporated herein by reference.

### BACKGROUND

### 1. Field

Aspects of embodiments of the present disclosure relate to a display device and a method of manufacturing the display device.

### 2. Description of the Related Art

Display devices, such as liquid crystal displays (LCD) and organic light emitting diode displays (OLED displays), include a display panel including a plurality of pixels for displaying images.

Each pixel includes a pixel electrode that receives a data signal, a plurality of transistors and one or more capacitors that transmit the data signal to the pixel electrode, and a common electrode opposing (or opposite to) the pixel electrode.

At least one layer may be located between the pixel electrode and the common electrode.

A common electrode can be formed across a plurality of pixels to transmit a constant (or common) voltage to each pixel.

### SUMMARY

If there is a voltage drop in the common voltage transmitted by the common electrode, unevenness may occur in the luminance of the image displayed by the display panel. For example, as display devices become larger, defects due to luminance unevenness due to a voltage drop at the common electrode may become more noticeable.

Embodiments of the present disclosure increase contact stability between the common electrode and an auxiliary electrode and increase process stability in a structure that forms the auxiliary electrode that is electrically connected to the common electrode to reduce voltage drop of a voltage transmitted by the common electrode.

Additionally, embodiments of the present disclosure provide a display device exhibiting reduced voltage drop at the common electrode without requiring additional processes and structures for contact between the auxiliary electrode and the common electrode.

The display device, according to an embodiment, includes a substrate, a light emitting diode including a common electrode on the substrate, a first conductive layer on the common electrode and contacting the common electrode, a first insulating layer on the first conductive layer and having a first contact opening on the first conductive layer, and a common voltage line on the first insulating layer. The common voltage line is electrically connected to the first conductive layer through the first contact opening.

The first contact opening may not overlap the light emitting diode on a plane.

The first conductive layer may include a conductive metal oxide.

The first conductive layer may include IGZO.

The common voltage line may include a lower layer, a middle layer, and an upper layer sequentially stacked on each other. The lower layer and the upper layer may include at least one of a first metal or a nitride of the first metal, and the middle layer may include a second metal different from the first metal.

The first metal may include titanium (Ti).

The second metal may include aluminum (Al).

The first insulating layer may include an inorganic insulating material.

The display device may further include a second conductive layer above the first insulating layer, and the second conductive layer may have a second contact opening corresponding to the first contact aperture. The common voltage line may be electrically connected to the first conductive layer through the first contact opening and the second contact opening.

The second conductive layer may include a conductive metal oxide.

The second conductive layer may include IGZO.

The second conductive layer may contact the upper surface of the first insulating layer.

The common voltage line may have a bottom surface contacting the first conductive layer, a side surface contacting the side surfaces of the first insulating layer and the second conductive layer in the first contact opening and the second contact opening, and a lower surface contacting an upper surface of the second conductive layer outside of the first contact opening.

The display device may further include: a second insulating layer on the common voltage line; and a third insulating layer on the second insulating layer. The second insulating layer may include an organic insulating material, the third insulating layer may include an inorganic insulating material, and the first insulating layer, the second insulating layer, and the third insulating layer may together cover the light emitting diode.

A display device, according to another embodiment, includes a substrate; a light emitting diode including a common electrode on the substrate; a first conductive layer on the common electrode; a first insulating layer on the first conductive layer; a second conductive layer on the first insulating layer; and a common voltage line on the second conductive layer. The first insulating layer and the second conductive layer each have a contact opening above the first conductive layer, and the common voltage line is electrically connected to the first conductive layer through the contact openings.

The first conductive layer and the second conductive layer may include a conductive metal oxide.

The first conductive layer and the second conductive layer may include IGZO.

The display device may further include: a second insulating layer on the common voltage line; and a third insulating layer on the second insulating layer. The first insulating layer and the third insulating layer may include an inorganic insulating material, the second insulating layer may include an organic insulating material, and the first insulating layer, the second insulating layer, and the third insulating layer may together cover the light emitting diode.

A method of manufacturing a display device, according to an embodiment, includes: forming a light emitting diode including a common electrode on a substrate; forming a first conductive layer including a conductive metal oxide on the common electrode; forming a first insulating layer including an inorganic insulating material on the first conductive layer; forming a second conductive layer including a conductive metal oxide on the first insulating layer; etching the second conductive layer to form a first contact opening above the first conductive layer; etching the first insulating layer to form a second contact opening corresponding to the first contact opening; and forming a common voltage line on the second conductive layer. The common voltage line is electrically connected to the first conductive layer through the first contact opening and the second contact opening.

The first conductive layer and the second conductive layer may include IGZO, the forming of the first contact opening may include a wet etching process, the forming of the second contact opening may include a dry etching process, and the forming of the common voltage line may include a dry etching process.

According to embodiments, to reduce the voltage drop of the voltage transmitted by the common electrode, the contact stability and process stability of the common electrode and the auxiliary electrode can be improved by using a structure that forms an auxiliary electrode electrically connected to the common electrode.

Additionally, the voltage drop of the common electrode can be reduced without any additional processes or structures for contact between the auxiliary electrode and the common electrode, and the same effect can be achieved in high-resolution display devices.

### BRIEF DESCRIPTION OF DRAWINGS

FIG. 1 is a plan view of an electrode layer and a common voltage line in one pixel of a display area of a display device according to an embodiment.

FIG. 2 is a cross-sectional view of one pixel of a display device according to an embodiment.

FIG. 3 is a cross-sectional view of a portion of a display device according to one embodiment.

FIG. 4 and FIG. 5 are cross-sectional views of a common voltage line of a display device according to embodiments, respectively.

FIG. 6 to FIG. 9 are cross-sectional views of steps of a method of manufacturing a display device according to an embodiment.

### DETAILED DESCRIPTION

Hereinafter, with reference to the attached drawings, various embodiments of the present disclosure will be described, in detail, so that those skilled in the art can easily implement the present invention.

The present disclosure may be implemented in many different forms and is not limited to the embodiments described herein.

To more clearly explain aspects and features of the present disclosure, parts of the disclosed embodiments that are not relevant to the description may be omitted and identical or similar components are assigned the same reference numerals throughout the specification.

In addition, the size and thickness of each component shown in the drawings may be arbitrarily shown for convenience of explanation so the present disclosure is not necessarily limited to that which is shown.

In the drawings, thicknesses may be enlarged to clearly express various layers and areas.

And in the drawings, for convenience of explanation, the thicknesses of some layers and regions may be exaggerated.

Additionally, when a part of a layer, membrane, region, or plate is said to be “above” or “on” another part, this includes not only cases where it is “directly above” another part but also cases where there is another part in-between.

Conversely, when a part is said to be “right on top” or “directly on top” of another part, it means that there is no other part in-between.

In addition, being “above” or “on” a reference part means being located above or below the reference part and does not necessarily mean being located “above” or “on” in the direction opposite to gravity.

In addition, throughout the specification, when a part is said to “include” a certain component, this means that it may also include other components rather than excluding other components, unless specifically stated to the contrary.

In addition, throughout the specification, when reference is made to “on a plane,” this means when the target portion is viewed from above, and when reference is made to “in a cross-section,” this means when a cross-section of the target portion is cut vertically and viewed from the side.

As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise.

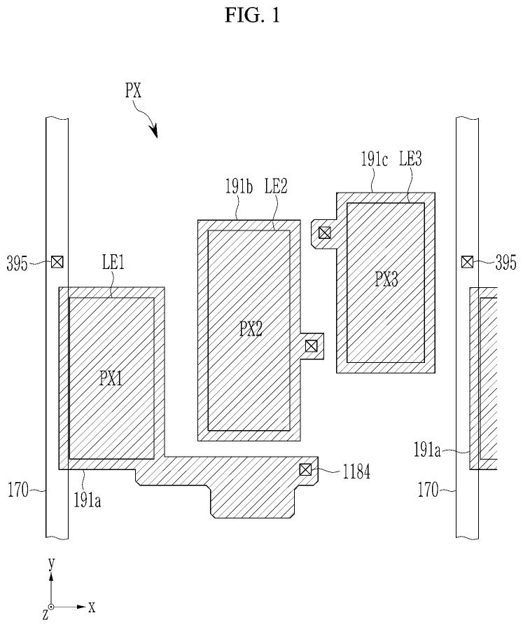

A display device according to an embodiment will be described with reference to FIG. 1.

FIG. 1 is a plan view of one electrode layer and a common voltage line in one pixel of a display area of a display device according to an embodiment.

Referring to FIG. 1, a display device according to an embodiment has a display area, and a plurality of pixels PX, which are units capable of displaying or configured to display an image, are arranged in the display area.

The plurality of pixels PX may be arranged in a roughly (or substantially) a matrix form on a plane in the display area, but the present disclosure is not limited to this and the plurality of pixels PX may be arranged repeatedly in various arrangements.

Each pixel PX may include a plurality of sub-pixels PX1, PX2, and PX3.

The plurality of sub-pixels PX1, PX2, and PX3 included in each pixel PX may display (or emit) light of different colors.

For example, the sub-pixels PX1, PX2, and PX3 can individually display basic colors, such as red, green, and blue.

The display device is configured to display images of various colors by combining various luminances of different basic colors displayed by the plurality of sub-pixels PX1, PX2, and PX3.

Each sub-pixel PX1, PX2, and PX3 may have a light-emitting area LE1, LE2, and LE3, respectively.

Each sub-pixel PX1, PX2, and PX3 may include a pixel electrodes 191a, 191b, and 191c, respectively, for receiving a data signal containing luminance information of the display light (e.g., of the light to be displayed or emitted) and a plurality of transistors electrically connected thereto.

The plurality of pixel electrodes 191a, 191b, and 191c are located (or arranged) on the same layer on the substrate and may include the same material.

Each pixel electrode 191a, 191b, and 191c may be electrically connected to each transistor formed in each sub-pixel PX1, PX2, and PX3, respectively, through an opening (e.g., a hole) 1184, which is formed in (or formed through) at least one insulating layer between the substrate and the corresponding pixel electrodes 191a, 191b, and 191c.

Each pixel electrode 191a, 191b, and 191c may overlap each light emitting area LE1, LE2, and LE3 on a plane.

A display device, according to an embodiment, may include a plurality of common voltage lines 170 that transmit a common voltage.

The common voltage line 170 may extend approximately in a first direction (e.g., in the y-direction in the drawings).

The common voltage line 170 may be located for each one or more pixels PX in a second direction (e.g., the x-direction in drawings) perpendicular to the first direction.

FIG. 1 shows an embodiment in which one common voltage line 170 is located for (or extends through or next to) each pixel PX in the second direction, but the present disclosure is not limited to this.

The common voltage line 170 may be located on a conductive layer different from the pixel electrodes 191a, 191b, and 191c on the substrate.

According to an embodiment, the common voltage line 170 may be located in a conductive layer located above the pixel electrodes 191a, 191b, and 191c on the substrate.

The common voltage line 170 may overlap the plurality of first contact openings 395 on a plane.

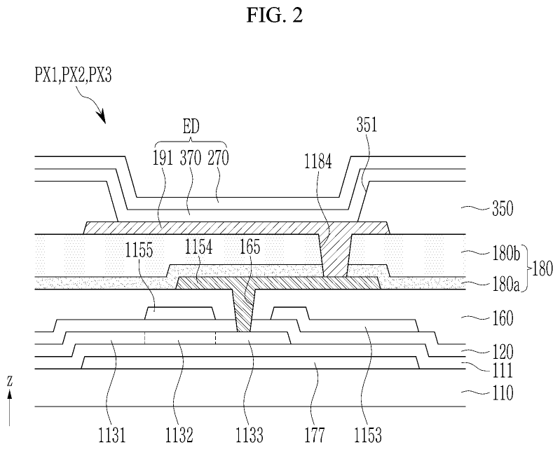

A detailed structure of a display device according to an embodiment will be described with reference to FIGS. 2 to 5 along with FIG. 1.

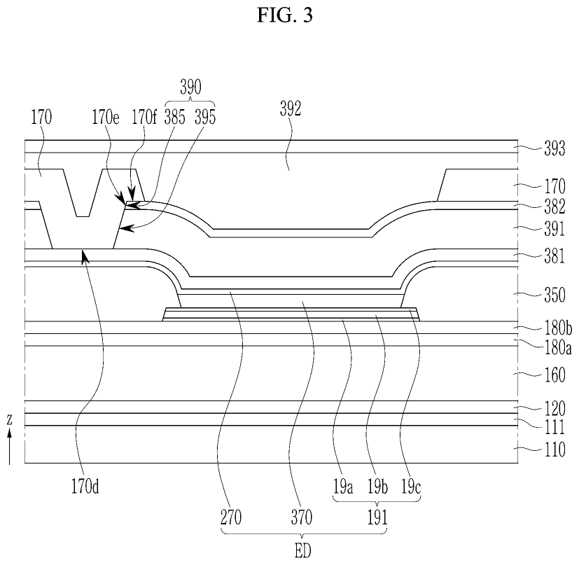

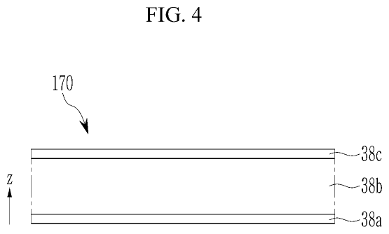

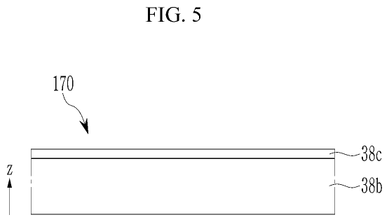

FIG. 2 is a cross-sectional view of a pixel of a display device according to an embodiment, FIG. 3 is a cross-sectional view of a display device according to an embodiment, and FIGS. 4 and 5 are cross-sectional views of a common voltage line of a display device according to embodiments.

A display device, according to an embodiment, includes a substrate 110 that may include (or may be formed of) glass, quartz, or plastic, such as polyimide, and a buffer layer 111, which is an insulating layer, may be located on the substrate 110.

A first conductive layer including a light blocking pattern 177 may be positioned between the substrate 110 and the buffer layer 111.

A semiconductor layer including a channel region 1132, and conductive regions 1131 and 1133 located on both sides of the channel region 1132, may be located on the buffer layer 111.

The conductive region 1131 located on one side of the channel region 1132 may be a source region, and the conductive region 1133 located on the other side of the channel region 1132 may be a drain region, or vice versa.

The source region and drain region may be referred to as a source electrode and a drain electrode, respectively.

A first insulating layer 120 may be located on the semiconductor layer.

A second conductive layer including a gate electrode 1155 and a lower electrode 1153 may be positioned on the first insulating layer 120.

The gate electrode 1155 may overlap the channel region 1132 in a vertical direction (e.g., in the z-direction in the drawings).

The gate electrode 1155 may be electrically connected to the lower electrode 1153 and, in some embodiments, may be formed together with the lower electrode 115 as one body.

The channel region 1132, the conductive regions 1131 and 1133, and the gate electrode 1155 may together form one transistor.

A second insulating layer 160 may be positioned on the gate electrode 1155 and the lower electrode 1153.

A third conductive layer including an upper electrode 1154 may be positioned on the second insulating layer 160.

The upper electrode 1154 may form a capacitor by overlapping the lower electrode 1153 with the second insulating layer 160 therebetween.

The lower electrode 1153 may also overlap the light blocking pattern 177 with the first insulating layer 120 interposed therebetween.

The upper electrode 1154 may be electrically connected to the conductive region 1133 of the transistor through the opening 165 formed in the second insulating layer 160 and the first insulating layer 120.

A third insulating layer 180 may be positioned on the upper electrode 1154.

The third insulating layer 180 may include a first protective layer 180a and a second protective layer 180b.

The third insulating layer 180 may have a plurality of openings 1184.

At least one of the first conductive layer, the second conductive layer, and the third conductive layer may include (or may contain) copper (Cu), aluminum (Al), magnesium (Mg), silver (Ag), gold (Au), platinum (Pt), palladium (Pd), nickel (Ni), neodymium (Nd), iridium (Ir), molybdenum (Mo), tungsten (W), titanium (Ti), chromium (Cr), tantalum (Ta), etc. and may include at least one metal oxide, such as an alloy of the above listed elements, ITO (Indium Tin Oxide), and IZO (Indium Zinc Oxide).

Each of the first conductive layer, the second conductive layer, and the third conductive layer may be made of a single layer or may include multiple layers.

For example, at least one of the first conductive layer, the second conductive layer, and the third conductive layer may have a multi-layer structure including a lower layer including (or containing) titanium, a middle layer including (or containing) copper, and an upper layer including (or containing) ITO.

At least one of the buffer layer 111, the first insulating layer 120, the second insulating layer 160, and the third insulating layer 180 may include (or may be made of) silicon nitride (SiNₓ), silicon oxide (SiOₓ), silicon oxynitride (SiOₓN_{y}), etc. At least one of the buffer layer 111, the first insulating layer 120, the second insulating layer 160, and the third insulating layer 180 may include an inorganic insulating material and/or an organic insulating material, such as polyimide, acrylic polymer, or siloxane polymer.

The first protective layer 180a of the third insulating layer 180 may include (or may be made of) an inorganic insulating material, and the second protective layer 180b may include (or may be made of) an organic insulating material.

A fourth conductive layer including a plurality of pixel electrodes 191 may be positioned on the third insulating layer 180.

The pixel electrode 191 may include a plurality of pixel electrodes 191a, 191b, and 191c, as shown in, for example, FIG. 1.

The fourth conductive layer may include a transparent metal oxide, such as indium tin oxide ITO or indium zinc oxide IZO.

The fourth conductive layer may be made of a single layer or may include multiple layers.

Referring to FIG. 3, the fourth conductive layer may have a multilayer structure, such as a triple layer structure, in which a lower layer 19a including ITO, a middle layer 19b including silver (Ag), and an upper layer 19c including ITO are sequentially laminated, for example.

The pixel electrode 191 may be electrically connected to the upper electrode 1154 through the opening 1184.

A fourth insulating layer 350 may be positioned on the pixel electrode 191.

The fourth insulating layer 350 may include an organic insulating material, such as polyimide, polyamide, acrylic resin, benzocyclobutene (BCB), or a phenol resin, or a silica-based inorganic insulating material.

The fourth insulating layer 350 may have a pixel opening 351 that overlaps the pixel electrode 191.

A light emitting layer 370 may be located on the fourth insulating layer 350.

The light emitting layer 370 may include low molecular weight organic materials or high molecular weight organic materials, such as PEDOT (Poly(3,4-ethylenedioxythiophene)).

The light emitting layer 370 includes one or more of a hole injection layer HIL, a hole transporting layer HTL, an electron transporting layer ETL, and an electron injection layer EIL and may further include one or more other layers.

The light emitting layer 370 may be located mostly within the pixel opening 351 and may include a portion located on the fourth insulating layer 350.

At least a portion of the light emitting layer 370 may be formed through a deposition process.

At least a portion of the light emitting layer 370 may be located within the pixel opening 351 of the fourth insulating layer 350 and may be in contact with the pixel electrode 191.

A common electrode 270 is located on the light emitting layer 370.

The common electrode 270 may be formed of a single (or integral) conductor across a plurality of pixels.

The common electrode 270 may be positioned entirely on (e.g., may entirely cover) the display area of the substrate 110.

The common electrode 270 may include a metal material including (or containing) silver (Ag) or a transparent metal oxide, such as indium tin oxide ITO or indium zinc oxide IZO.

The pixel electrode 191, the light emitting layer 370, and the common electrode 270 of each sub-pixel PX1, PX2, and PX3 together form a light emitting diode ED, which is a light emitting device.

The pixel electrode 191 may be an anode, and the common electrode 270 may be a cathode, but the opposite is also possible.

A lower conductive layer 381 may be positioned on the common electrode 270.

The lower conductive layer 381 may be formed of a single conductor across a plurality of pixels and may be entirely located on (e.g., may entirely cover) the display area of the substrate 110.

The lower conductive layer 381 may include a portion overlapping the light emitting diode ED and a portion overlapping the fourth insulating layer 350.

The lower conductive layer 381 may be in contact with the upper surface of the common electrode 270 and is electrically connected to the common electrode 270 to transmit the common voltage received from the common voltage line 170, which will be described later, to the common electrode 270.

The lower conductive layer 381 may include a conductive metal oxide and a material that can be wet etched rather than dry etched.

For example, the material included in (or forming) the lower conductive layer 381 may have high dry etching selectivity with the fifth insulating layer 391, which will be described later.

The lower conductive layer 381 may include, for example, IGZO having conductive properties.

When the lower conductive layer 381 includes IGZO, the lower conductive layer 381 is formed by depositing IGZO using argon gas (Ar) rather than oxygen gas (O₂) when stacking the lower conductive layer 381.

The lower conductive layer 381 may act as an etch stopper for the common electrode 270 and the fourth insulating layer 350 below it during the etching process when forming the first contact opening 395, which will be described later.

For example, the lower conductive layer 381 prevents the common electrode 270 and the fourth insulating layer 350 below it from being damaged and lost (or etched and removed) during the etching process for forming the first contact opening 395.

The thickness (e.g., the z-direction thickness) of the lower conductive layer 381 may be greater than the thickness (e.g., the z-direction thickness) of the common electrode 270, but the present disclosure is not limited thereto.

A fifth insulating layer 391 may be located on the lower conductive layer 381.

The fifth insulating layer 391 may form a part of the encapsulation portion and may block the inflow of external moisture and oxygen by covering and sealing the light emitting diode ED, which is a light emitting device.

The fifth insulating layer 391 may include an inorganic insulating material, such as silicon oxide (SiOₓ), silicon nitride (SiNₓ), or silicon oxynitride (SiOₓN_{y}).

The thickness (e.g., the z-direction thickness) of the fifth insulating layer 391 may be in a range of approximately 100 angstroms to approximately 1000 angstroms but is not limited thereto.

The fifth insulating layer 391 may have a first contact opening 395 exposing the lower conductive layer 381 in an area that does not overlap (e.g., offset from) the light emitting diode ED.

The fifth insulating layer 391 may be completely removed at an area to form the first contact opening 395.

The first contact opening 395 may be located to overlap the fourth insulating layer 350.

The first contact opening 395 may be formed by a dry etching process.

An upper conductive layer 382 may be located on the fifth insulating layer 391.

The upper conductive layer 382 may be formed of a single conductor across a plurality of pixels and may be entirely located on (e.g., may entirely cover) the display area of the substrate 110.

The upper conductive layer 382 may include a portion overlapping the light emitting diode ED and a portion overlapping the fourth insulating layer 350.

The upper conductive layer 382 may cover the fifth insulating layer 391.

A fifth insulating layer 391 may be located between the lower conductive layer 381 and the upper conductive layer 382.

The upper conductive layer 382 may include a conductive metal oxide and may include a material that can be wet etched rather than dry etched.

The material included in the upper conductive layer 382 may have high dry etching selectivity with respect to the common voltage line 170.

The upper conductive layer 382 may include, for example, IGZO having conductive properties.

When the upper conductive layer 382 includes IGZO, the upper conductive layer 382 is formed by depositing IGZO using argon gas (Ar) rather than oxygen gas (O₂) when depositing the upper conductive layer 382.

The upper conductive layer 382 may have a second contact opening 385 that corresponds to and overlaps the first contact opening 395.

The second contact opening 385 and the first contact opening 395 may together form one contact opening 390.

The second contact opening 385 may be formed by a wet etching process.

The upper conductive layer 382 may act as an etch prevention layer for the fifth insulating layer 391 in an etching process for forming the common voltage line 170, which will be described later.

For example, the upper conductive layer 382 may prevent the fifth insulating layer 391 from being damaged and lost (e.g., etched and removed) during the dry etching process of the common voltage line 170.

The thickness (e.g., the z-direction thickness) of the upper conductive layer 382 may be greater than the thickness (e.g., the z-direction thickness) of the common electrode 270, but the present disclosure is not limited thereto.

The thickness (e.g., the z-direction thickness) of the lower conductive layer 381 and the upper conductive layer 382 may be smaller than the thickness (e.g., the z-direction thickness) of the fifth insulating layer 391, but the present disclosure is not limited thereto.

A common voltage line 170 may be located on the upper conductive layer 382.

The common voltage line 170 may transmit a common voltage and may be referred to as an auxiliary electrode.

The common voltage line 170 may receive a common voltage from outside the display area.

The common voltage line 170 may be electrically connected by contacting the lower conductive layer 381 through the contact opening 390 and may transmit a common voltage to the lower conductive layer 381.

Accordingly, the common electrode 270, which is in contact with the lower conductive layer 381, can receive the common voltage from the common voltage line 170.

Accordingly, the common electrode 270 receives the common voltage from the common voltage line 170 at periodic positions within the display area, thereby reducing voltage drop.

The common voltage line 170 has a bottom surface 170d in contact with the lower conductive layer 381, a side surface 170e in contact with the side surface of the fifth insulating layer 391 and the upper conductive layer 382 in the contact opening 390 and may have a lower surface 170f that contacts the upper surface of the upper conductive layer 382 outside (e.g., adjacent to) the contact opening 390.

Because the common voltage line 170 is electrically connected to the upper conductive layer 382, the upper conductive layer 382 can also transmit the common voltage.

According to the illustrated embodiment, stable contact characteristics between the common electrode 270 and the common voltage line 170 can be secured.

Additionally, the voltage drop of the common electrode 270 may be reduced without any additional processes or structures, such as laser drilling, to pierce the light emitting layer for contact between the common electrode 270 and the common voltage line 170, thus making it easier to implement high-resolution display devices.

The common voltage line 170 may include a conductive metal.

For example, the common voltage line 170 may include a metal that has good contact characteristics with the lower conductive layer 381 and the upper conductive layer 382.

For example, referring to FIG. 4, the common voltage line 170 may include multiple layers including a lower layer 38a, a middle layer 38b, and an upper layer 38c stacked sequentially from the bottom.

The lower layer 38a, which may be in contact with the lower conductive layer 381 and the upper conductive layer 382, may include at least one of a first metal or a nitride of the first metal.

For example, the first metal may include (or may be) titanium (Ti).

When the lower layer 38a includes titanium nitride (TiN), contact characteristics between the common voltage line 170 and the lower conductive layer 381 and the upper conductive layer 382 may be improved.

The middle layer 38b located between the lower layer 38a and the upper layer 38c may include a second metal different from the first metal.

The second metal may have a lower resistance than the first metal.

For example, the second metal may include (or may be) aluminum (Al).

The upper layer 38c may include at least one of a third metal or a nitride of the third metal.

The third metal may be the same as the first metal.

The third metal may include, for example, titanium (Ti).

The common voltage line 170 may be patterned by dry etching.

For example, the material included in the common voltage line 170 may be patterned by dry etching.

Referring to FIG. 5, different from the embodiment shown in FIG. 4, the common voltage line 170 according to an embodiment may omit at least one of the lower layer 38a and the upper layer 38c.

FIG. 5 shows an embodiment in which the lower layer 38a of the common voltage line 170 is omitted compared to the embodiment shown in FIG. 4.

Referring again to FIG. 3, a sixth insulating layer 392 may be positioned on the common voltage line 170 and the upper conductive layer 382.

The sixth insulating layer 392 may form a part of the encapsulation portion together with the fifth insulating layer 391 and may block the inflow of external moisture and oxygen by covering and sealing the light emitting diode ED.

The sixth insulating layer 392 may include an organic insulating material and may have a thickness (e.g., a thickness in the z-direction) that is greater than the thickness (e.g., the z-direction thickness) of the fifth insulating layer 391.

A seventh insulating layer 393 may be located on the sixth insulating layer 392.

The seventh insulating layer 393 may form part of the sealing portion together with the fifth insulating layer 391 and the sixth insulating layer 392 and covers and seals the light emitting diode ED to prevent the inflow of external moisture and oxygen.

The seventh insulating layer 393 may include an inorganic insulating material, such as silicon oxide (SiOₓ), silicon nitride (SiNₓ), or silicon oxynitride (SiOₓN_{y}).

The thickness (e.g., the z-direction thickness) of the fifth insulating layer 391 may be in a range of approximately 100 angstroms to approximately 1000 angstroms but is not limited thereto.

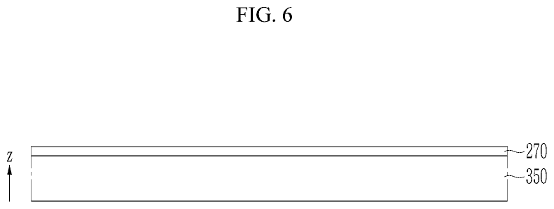

A method of manufacturing a display device according to an embodiment will be described with reference to FIGS. 6 to 9 along with the previously described drawings.

FIG. 6 to FIG. 9 are cross-sectional views of steps of a method of manufacturing a display device according to an embodiment.

First, referring to FIGS. 2, 3, and 6, a first conductive layer, a buffer layer 111, a semiconductor layer, a first insulating layer 120, a second conductive layer, a second insulating layer 160, a third conductive layer, a third insulating layer 180, a fourth conductive layer, a fourth insulating layer 350, a light emitting layer 370, and a common electrode 270 are sequentially laminated and patterned on the substrate 110.

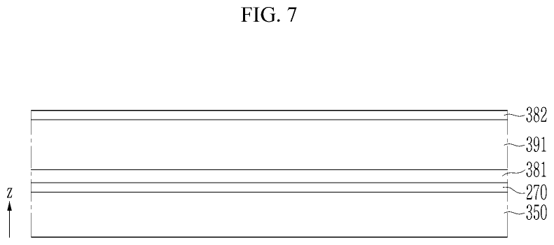

Next, referring to FIG. 7, a conductive metal oxide, such as IGZO, is deposited on the common electrode 270 to form a lower conductive layer 381.

When depositing IGZO, argon gas (Ar) may be used instead of oxygen gas (O₂).

Next, an inorganic insulating material, such as silicon oxide (SiOₓ), silicon nitride (SiNₓ), or silicon oxynitride (SiOₓN_{y}), is stacked on the lower conductive layer 381 to form a fifth insulating layer 391.

Next, a conductive metal oxide, such as IGZO, is deposited on the fifth insulating layer 391 to form an upper conductive layer 382.

When depositing IGZO, argon gas (Ar) may be used instead of oxygen gas (O₂).

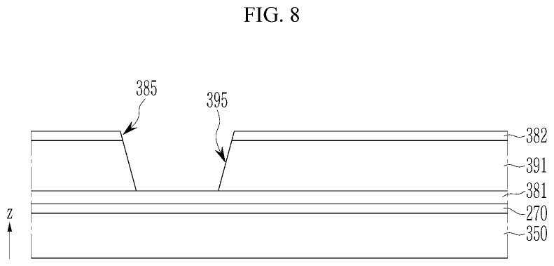

Next, referring to FIG. 8, the upper conductive layer 382 is patterned to form a plurality of second contact openings 385.

At this time, an etch mask, such as a photoresist, can be formed and a wet etching process can be used.

Next, the fifth insulating layer 391 is patterned by using the etch mask used to form the second contact opening 385 to form a plurality of first contact openings 395 corresponding to the second contact opening 385.

At this time, a dry etching process may be used.

In this process, the lower conductive layer 381, which has higher dry etching selectivity than the fifth insulating layer 391, acts as an etch prevention layer to prevent the relatively thin common electrode 270 from being etched and damaged.

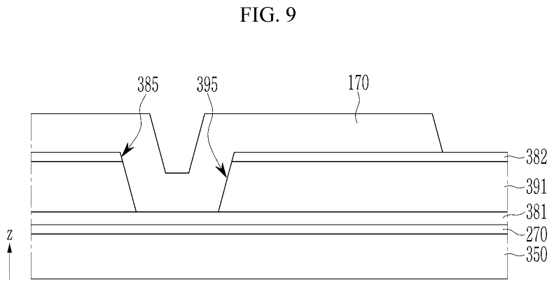

Next, referring to FIG. 9, a conductive material including (or containing) metal is stacked on the upper conductive layer 382 and patterned to form a common voltage line 170.

At this time, a dry etching process may be used.

In this process, the upper conductive layer 382, which has higher dry etching selectivity compared to the common voltage line 170, acts as an etch prevention layer to prevent the fifth insulating layer 391 from being etched and damaged.

The common voltage line 170 is also formed in the first contact opening 395 and the second contact opening 385 so that it contacts the lower conductive layer 381 and conducts electricity thereto.

According to an embodiment, the manufacturing process is relatively simple without the need for additional processes, such as laser drilling for contacting the common voltage line or the auxiliary electrode and the common electrode, resulting in high process stability and easy implementation.

Although embodiments of the present disclosure have been described in detail above, the scope of the present disclosure is not limited thereto, and various modifications and improvements made by those skilled in the art according to the basic concepts of the present disclosure as defined in the following claims and their equivalents.

### DESCRIPTION OF SOME REFERENCE NUMERALS

110: substrate
111: buffer layer
120, 160, 180, 350, 383, 391, 392, 393: insulating layer
165, 1184: opening
170: common voltage line
177: light blocking pattern
191, 191a, 191b, 191c: pixel electrode
270: common electrode
370: light emitting layer
381: lower conductive layer
382: upper conductive layer
385, 390, 395: contact opening
1131, 1133: conductive region
1132: channel region
1153: lower electrode
1154: upper electrode
1155: gate electrode

What is claimed is:

1. A display device comprising:
a substrate;
a light emitting diode comprising a common electrode on the substrate;
a first conductive layer on the common electrode and contacting the common electrode;
a first insulating layer over the first conductive layer and having a first contact opening over the first conductive layer; and
a common voltage line on the first insulating layer and electrically connected to the first conductive layer through the first contact opening.

2. The display device of claim 1, wherein the first contact opening does not overlap the light emitting diode on a plane.

3. The display device of claim 2, wherein the first conductive layer comprises a conductive metal oxide.

4. The display device of claim 3, wherein the first conductive layer comprises IGZO.

5. The display device of claim 1, further comprising a lower layer, a middle layer, and an upper layer sequentially stacked on the common voltage line,
wherein the lower layer and the upper layer comprise at least one of a first metal or a nitride of the first metal, and
wherein the middle layer comprises a second metal different from the first metal.

6. The display device of claim 5, wherein the first metal comprises titanium.

7. The display device of claim 6, wherein the second metal comprises aluminum.

8. The display device of claim 1, wherein the first insulating layer comprises an inorganic insulating material.

9. The display device of claim 1, further comprising a second conductive layer on the first insulating layer,
wherein the second conductive layer has a second contact opening corresponding to the first contact opening, and
wherein the common voltage line is electrically connected to the first conductive layer through the first contact opening and the second contact opening.

10. The display device of claim 9, wherein the second conductive layer comprises a conductive metal oxide.

11. The display device of claim 10, wherein the second conductive layer comprises IGZO.

12. The display device of claim 9, wherein the second conductive layer contacts an upper surface of the first insulating layer.

13. The display device of claim 9, wherein the common voltage line has a bottom surface contacting the first conductive layer, a side surface contacting the side surfaces of the first insulating layer and the second conductive layer in the first contact opening and the second contact opening, and a lower surface contacting an upper surface of the second conductive layer outside of the first contact opening.

14. The display device of claim 1, further comprising:
a second insulating layer on the common voltage line; and
a third insulating layer on the second insulating layer,
wherein the second insulating layer comprises an organic insulating material,
wherein the third insulating layer comprises an inorganic insulating material, and
wherein the first insulating layer, the second insulating layer, and the third insulating layer together cover the light emitting diode.

15. A display device comprising:
a substrate;
a light emitting diode comprising a common electrode on the substrate;
a first conductive layer on the common electrode;
a first insulating layer on the first conductive layer;
a second conductive layer on the first insulating layer; and
a common voltage line on the second conductive layer,
wherein the first insulating layer and the second conductive layer each have a contact opening above the first conductive layer, and
wherein the common voltage line is electrically connected to the first conductive layer through the contact openings.

16. The display device of claim 15, wherein the first conductive layer and the second conductive layer comprise a conductive metal oxide.

17. The display device of claim 16, wherein the first conductive layer and the second conductive layer comprise IGZO.

18. The display device of claim 15, further comprising:
a second insulating layer on the common voltage line; and
a third insulating layer on the second insulating layer,
wherein the first insulating layer and the third insulating layer comprise an inorganic insulating material,
wherein the second insulating layer comprises an organic insulating material, and
wherein the first insulating layer, the second insulating layer, and the third insulating layer together cover the light emitting diode.

19. A method of manufacturing a display device, the method comprising:
forming a light emitting diode comprising a common electrode on a substrate;
forming a first conductive layer comprising a conductive metal oxide on the common electrode;
forming a first insulating layer comprising an inorganic insulating material on the first conductive layer;
forming a second conductive layer comprising a conductive metal oxide on the first insulating layer;
etching the second conductive layer to form a first contact opening above the first conductive layer;
etching the first insulating layer to form a second contact opening corresponding to the first contact opening; and
forming a common voltage line on the second conductive layer,
wherein the common voltage line is electrically connected to the first conductive layer through the first contact opening and the second contact opening.

20. The method of manufacturing a display device of claim 19, wherein the first conductive layer and the second conductive layer comprise IGZO,
wherein the forming of the first contact opening comprises a wet etching process,
wherein the forming of the second contact opening comprises a dry etching process, and
wherein the forming of the common voltage line comprises a dry etching process.
